(19) United States
(12) Patent Application Publication
(10) Pub. No.: US 2011/0195199 A1
(43) Pub. Date: Aug. 11, 2011

(54) PROCESS AND DEVICE FOR SOLDERING IN THE VAPOR PHASE

(76) Inventors: Marco Huber, Aschaffenburg (DE); Wolfgang Becker, Schaafheim (DE); Patrick Binkowska, Westemgrund (DE); Bemhard Cord, Alzenau (DE); Oliver Hohn, Grundau (DE); Stefan Kempf, Alzenau (DE); Michael Reising, Mombris (DE); Björn Roos, Freigericht (DE); Edgar Rüth, Kahl am Main (DE); Eggo Sichmann, Gelnhausen (DE); Peter Wohlfart, Kahl am Main (DE)

(21) Appl. No.: 12/737,900

(22) PCT Filed: Aug. 26, 2009
(86) PCT No.: PCT/EP2009/060994

§ 371 Date: Apr. 22, 2011

(30) Foreign Application Priority Data
Sep. 1, 2008 (DE) 10 2008 045 249.1
Apr. 23, 2009 (DE) 10 2009 018 700.6

(51) Int. Cl. H01L 31/18; C23C 16/50; C23C 16/44

(52) U.S. Cl. 427/534; 118/719; 427/569

(57) ABSTRACT

The invention provides a coating system for coating substrates in a cyclic mode. The process stations of the coating system are disposed in a circular fashion. A handling mechanism is provided for transferring the substrates between the process stations. The process stations comprise a lock for loading and unloading the substrates, at least two coating chambers, each of which comprises a plasma source for stationary coating of the substrate, and preferably a heating station.

### FIELD OF THE INVENTION

The invention relates to a system for coating substrates, in particular a vacuum coating system for coating silicon wafers, in particular for photovoltaics.

### BACKGROUND TO THE INVENTION

In a coating system, the process steps necessary for coating a substrate are carried out successively. Known systems operate either in the continuous mode, in which substrates pass through the system continuously, or in the so-called batch mode, in which a large batch of wafers is loaded into the vacuum system, processed and then unloaded.

### SUMMARY OF THE INVENTION

The present invention provides a coating system, in particular a vacuum coating system, which operates in the cyclic mode and in which the substrate flow is not necessarily but preferably circular. As process stations, the coating system comprises a lock for loading and unloading the substrate and at least two independently operating coating chambers for stationary coating, each of which is connected with a plasma source. Preferably, one or more heating stations is/are provided. For transferring the substrates between the process stations, there is provided a handling mechanism which operates under a vacuum and can be realized, e.g., in the form of a rotary plate which, by rotation, transports the substrates from one process station to the next and, therefore, generates a circular substrate flow.

In the coating system, a specific batch size of substrates is coated statically. For example, four silicon wafers can be treated simultaneously. One or more functional layers can be applied, such as a combined anti-reflex and passivation layer of poly- or mono-crystalline solar cells. The coating operation can be divided into a plurality of individual steps, for example three or more steps. One plasma source is provided for each coating step.

Each plasma source can be controlled individually and forms a separate coating chamber. Each coating chamber has an independent vacuum generation system and an adjustable gas supply. The substrates are preferably coated by the plasma-chemical decomposition of the gases introduced into the source (PECVD, Plasma Enhanced Chemical Vapor Deposition).

In an embodiment, silicon nitride (Si₃N₄) is deposited, i.e. from the precursor silane (SiH₄) and the reactive gas ammoniac (NH₃). Coating takes place preferably from the bottom to the top so that no particles fall onto the substrate. However, coating from the top to the bottom is also possible.

In addition to the actual coating, preferably a further process station is provided for heating the wafers. The substrates are preferably heated by heat radiation by a battery of infrared radiant heaters. Moreover, a free position can receive either an additional heater, a cooling station, a further coating source or in principle any further process station. The order of the functions of the individual process stations can be selected in accordance with the overall process.

The described system or machine can be integrated into large production lines. This means that the substrates are received from another machine in which preceding process steps take place and transmitted to following or downstream machines in which the substrates are finished. In such production lines, the individual machines are commonly connected by means of additional transporting means. In the present invention, these transporting means can already be integrated. In addition to the mere transport function, the transporting means can—like a generally usable handling mechanism—also perform the adjustment of the substrates and the transfer into a cyclic order. These two functions are not necessarily guaranteed by the upstream machine.

The substrate flow is preferably circular, so that in contrast to a linear machine, only one chamber is necessary for feeding and removing the substrates. Also only one handling mechanism is necessary, which serves for both loading and unloading the lock. Moreover, in accordance with this approach, the floor space required for the machine is minimized. By using a preferably small batch size of substrates, a small lock, which can be evacuated or flooded quickly, is sufficient. The volume of the process chambers and thus the consumption of process gases are minimized as well.

In the static coating process, the substrates are resting during the entire coating process in a stationary manner under a source that is stationary as well. In contrast to the dynamic process (in so-called continuous systems), in which the substrates move at a predetermined speed under the source, the static principle offers the advantage that the coating parameters can be changed in view of time. Therefore, it is possible to apply a gradient layer, i.e. a layer whose physical properties vary in the direction of its thickness, in one single coating chamber.

A further advantage of the static coating process is a coating that is decoupled from the transporting movement, so that reproducibility of the results is increased.

Since the coating chambers operate independently of one another, the gradient of or the variation in the layer properties can additionally be achieved within the individual steps. Basically, it is also possible to sequentially apply different layer materials. A coating system of this kind is particularly suitable for allowing new cell concepts in photovoltaics.

In the dynamic process, the uniformity of the layer must be controlled only along a line (perpendicular with respect to the path of movement). The uniformity on the substrate surface is achieved by the constant movement speed.

In the system according to the invention, the problem of a surface homogeneity can be solved by specific gas distributors for reactive and precursor gases as well as by an adapted geometry of the pump cross-section. The distribution of both gases as well as the distribution of the pump power are then superimposed by the predetermined distribution of the plasma density that a maximum homogeneity across the surface to be coated is achieved.

In addition to the substrates, also walls etc. of the process chamber are coated. The system uses preferably an etching process for self-cleaning. In this process, a cleaning gas is introduced through at least one gas distributor. Cleaning also takes place in a plasma enhanced manner. This self-cleaning can take place inline, without noticeable down time (interruption) and without any personnel being required. For realizing this principle, individual or all process chambers are preferably made of suitable materials that are resistant to the cleaning gas.

During the cleaning period, the production in the machine is interrupted. In the system according to the invention, however, it is possible to compensate for this interruption. The wafers which are delivered during the cleaning interval (duration: some minutes) by the upstream machine at a given cycle time t₀ are buffered in a temporary storage. When the cleaning has finished, a coating interval takes place (duration: some ten minutes). During this coating interval, the temporarily stored wafers are processed in addition to the still delivered wafers. This means that the coating machine described here operates with an actual cycle time t₁, wherein t₁ <t₀. Transfer to the downstream machine takes place in a similar manner: Additionally processed wafers are temporarily stored and delivered only during the cleaning interval. From outside, the machine thus operates in an effective cycle time which is also t₀ and results in a predetermined output of wafers per hour, which is equal for all components in the entire production line. The advantage is that cleaning takes place without noticeable standstill of the system and does not influence the remaining production chain.

The system can be connected as a module in parallel with further modules, so that the output can be multiplied. Due to this modular expansibility, the system concept can be integrated well into existing overall production lines with predetermined output. Also a sequential connection of a plurality of modules is possible for applying relatively thick layers, complex layer systems, or layer systems of materials with low deposition rate.

Because of the small batch sizes, only few substrates are simultaneously in the system or in the process. This simplifies quality control in which, e.g., inline measuring devices quickly determine quality variations in the coating and can pass on warnings before a relatively large number of wafers is processed incorrectly. Also a closed-loop control of the process parameters is possible.

Thus, the present invention provides an economical system in which parts such as locks and loading functions are in a balanced relation relative to the actual process chambers. The floor space required for the system is minimized and optimally used. Times for the required pumping down and flooding of the lock and for feeding the substrates into the coating chambers as well as for loading the substrates can be minimized. The layer properties can be specifically influenced by gradients or layer systems. Moreover, the requirements, in particular the personnel required for cleaning the system can be minimized or is not necessary at all. The output of the system can be increased. Cleaning of the system should not block the remaining production chain, a continuous output should be guaranteed.

Since conventional machines operate either in the continuous mode or in the batch mode, a variation of the layer properties is not possible. Moreover, in known machines the production batches are generally larger, which requires relatively involved locks and relatively long pump-down times. Known machines are normally constructed linearly. For cleaning, the known machines are as a rule put out of service after some days for a period of some hours. During this time period, the remaining production chain produces for the stock.

Thus, features of embodiments of the present invention are:

Small batch sizes and, therefore, minimization of the volume of lock and process chambers for achieving short loading times and for minimizing the amounts of process gas;

circular material flow and thus small floor space required, because feeding and removing and/or loading and unloading are combined;

static coating process and, therefore, well-aimed influence on the layer properties along the layer thickness;

independent coating chambers and, therefore, additional flexibility in the layer structure (systems of several layers are possible);

layer homogeneity because of optimized distribution of process gases and pump power;

inline cleaning concept without standstill period and, therefore, reduced personnel requirements and increased productivity;

flexibility with respect to wafer output per hour because of parallel, modular expansibility;

flexibility with respect to the applied layer system, layer material and layer thickness by serial, modular expansibility;

simple process control because few substrates are simultaneously in the process; and

recipe-controlled process and, therefore, high flexibility.

Thus, in particular the following advantages can be achieved: Short cycle periods, optimum consumption of the source materials, a small floor space required for the system, flexibility with respect to the layer architecture and, therefore, suitable for future cell concepts in which this fact can be decisive, high layer homogeneity, low personnel requirements, few standstill periods, high productivity, flexible output (production performance), simple process control, and closed-loop control.

In addition to silicon wafers, also other substrates having suitable dimensions can be coated. Also an arrangement in which substrates are coated on both sides is possible. There is no restriction in view of the process gases. The silicon nitride layer can be deposited with all further reaction gases or gaseous precursors and/or precursors that are converted into the gaseous phase by vaporizing, as far as they provide the required elements Si and N. Except for silicon nitride, each other layer can be applied as long as its components can be processed by plasma enhanced chemical vapor phase deposition. In addition to coating, the system can also be used for cleaning or structuring substrates by means of the described etching process.

### BRIEF DESCRIPTION OF THE DRAWINGS

In the following, the invention is described in more detail with reference to the enclosed drawings in which:

FIG. 1 shows a top view of a coating system according to an embodiment of the present invention;

FIG. 2 shows a lock with a batch of four wafers to be used in a coating system according to an embodiment of the present invention; and

FIG. 3 shows a handling mechanism for loading and unloading to be used with a coating system according to an embodiment of the present invention.

### DETAILED DESCRIPTION OF THE INVENTION

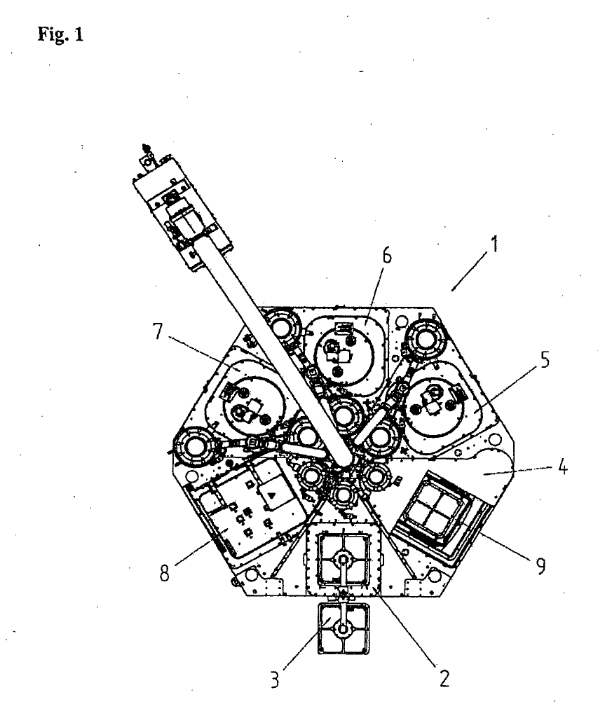

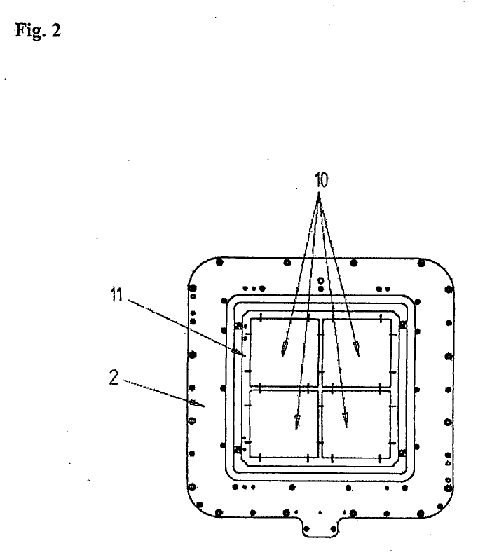

According to FIG. 1, a coating system 1 according to an embodiment of the invention comprises a lock 2 with a lock handling mechanism 3 and a plurality of process stations 4 to 8. Through the lock handling mechanism 3 with lock cover, a batch of substrates is transferred into the lock 2 of the coating system 1. A corresponding lock 2 with a batch of four wafers is shown in FIG. 2. The substrates or wafers 10 are arranged on a transport carrier 11 in groups of four substrates. This transport carrier 11 is transferred into the lock chamber 2. The coating system of the shown embodiment comprises three coating chambers 5 to 7 and a heating station 8. Additionally, a free process station 4 is provided, into which an additional heating station, a cooling station or a further or different coating chamber can be inserted according to requirements. The transport carriers 11 with the substrates 10 are transferred in the coating system 1 on a rotary table or plate 9 between the process stations.

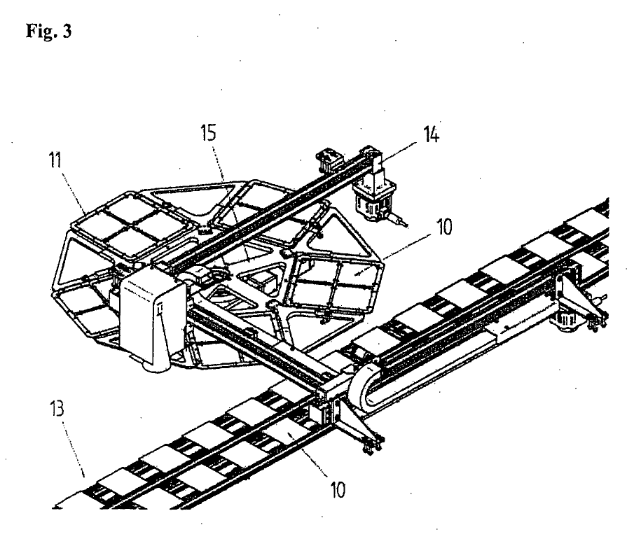

FIG. 3 shows a handling mechanism by means of which the coating system according to the present invention can be integrated into a present production line. The substrates 10, in particular wafers, supplied and removed via a delivery belt 13 integrated in the production line are delivered via a rotary plate 15 and a loading and unloading handling mechanism 14 to the coating system according to the invention and, after coating, again transferred back into the production line for further processing. In detail: The substrates or wafers 10 coming from the supply belt 13 are received, e.g., in groups of four substrates in a transport carrier 11 shown in FIG. 2. The substrates 10 are then transported on a rotary plate 15 to a loading and unloading handling mechanism 3 of FIG. 1 (lock handling mechanism), from where they are introduced into the coating system 1 via a lock 2 shown in FIG. 1. After coating, the substrates 10 are then transferred by the transport carriers 11 again via the loading and unloading handling mechanism 3 of FIG. 1 (lock handling mechanism) onto the rotary plate 15 and from the latter by means of the loading and unloading handling mechanism 14 back to the supply belt 13.

1. A coating system, in particular vacuum coating system, for coating substrates, comprising a plurality of process stations, a lock for loading and unloading the substrates and a handling mechanism for transferring the substrates between the process stations and between at least one process station and the lock, wherein the process stations comprise at least two independently operating coating chambers for stationary coating of the substrates, and the coating chambers are each connected with a plasma source.

2. The coating system according to claim 1, wherein the process stations are arranged in a circular manner.

3. The coating system according to claim 1, wherein the lock is a vacuum lock and the handling mechanism for transferring the substrates between the process stations is formed under vacuum.

4. The coating system according to claim 1, wherein a specific batch size, preferably four substrates, is/are processed simultaneously.

5. The coating system according to claim 1, further comprising at least one heating station.

6. The coating system according to claim 5, wherein the heating station comprises at least one infrared heater.

7. The coating system according to claim 1, further comprising at least one cooling station.

8. The coating system according to claim 1, further comprising a device for introducing a cleaning gas into the process stations, preferably for a plasma-chemical self-cleaning thereof.

9. The coating system according to claim 1, further comprising a buffer for temporarily storing substrates.

10. The coating system according to claim 1, further comprising a station for a plasma-chemical treatment, preferably for cleaning and/or structuring the substrates.

11. The coating system according to claim 1, wherein the substrates comprise silicon wafers, preferably for use in photovoltaics.

12. A method for coating substrates by using the coating system according to claim 1, comprising a preferably automatically running cleaning step between two coating steps.

13. A method for coating substrates by using the coating system according to claim 5, comprising a preferably automatically running cleaning step between two coating steps.

14. A method for coating substrates by using the coating system according to claim 7, comprising a preferably automatically running cleaning step between two coating steps.

15. A method for coating substrates by using the coating system according to claim 8, comprising a preferably automatically running cleaning step between two coating steps.

16. A method for coating substrates by using the coating system according to claim 10, comprising a preferably automatically running cleaning step between two coating steps.
